(19) United States
(12) Patent Application Publication
(10) Pub. No.: US 2025/0229530 A1
(43) Pub. Date: Jul. 17, 2025

(54) FLEXIBLE BOARD, LIQUID JET HEAD, AND LIQUID JET RECORDING APPARATUS

(71) Applicant: SII Printek Inc., Chiba-shi (JP)

(72) Inventor: Akihiro ITAGI, Chiba-shi (JP)

(21) Appl. No.: 19/016,794

(22) Filed: Jan. 10, 2025

(30) Foreign Application Priority Data
Jan. 17, 2024 (JP) 2024-005521

(51) Int. Cl. B41J 2/14; H05K 1/02

(52) U.S. Cl. CPC B41J 2/14201; H05K 1/0281; B41J 2002/14491

(57) ABSTRACT

A flexible board and so on capable of easily improving the reliability are provided. The flexible board according to an embodiment of the present disclosure is a flexible board configured to output a drive signal to be applied to a liquid jet head having a plurality of nozzles, including a plurality of wiring layers including a first wiring layer and a second wiring layer opposed to each other along a direction perpendicular to a surface of the board, one or a plurality of drive devices which are arranged in a first region of the first wiring layer, and which are configured to generate the drive signal configured to jet a liquid from the nozzle, and a deformation suppression part which is disposed in a second region of the second wiring layer, and which is configured to suppress a deformation of the flexible board.

### RELATED APPLICATIONS

This application claims priority to Japanese Patent application No. JP2024-005521, filed on Jan. 17, 2024, the entire content of which is incorporated herein by reference.

### BACKGROUND OF THE INVENTION

### 1. Field of the Invention

The present disclosure relates to a flexible board, a liquid jet head, and a liquid jet recording apparatus.

### 2. Description of the Related Art

Liquid jet recording apparatuses equipped with liquid jet heads are used in a variety of fields, and a variety of types of liquid jet heads are developed.

In such liquid jet heads, in general, it is required to easily improve the reliability.

Therefore, it is desirable to provide a flexible board, a liquid jet head, and a liquid jet recording apparatus capable of easily improving the reliability.

### SUMMARY OF THE INVENTION

A flexible board according to an embodiment of the present disclosure is a flexible board configured to output a drive signal to be applied to a liquid jet head having a plurality of nozzles, including a plurality of wiring layers including a first wiring layer and a second wiring layer opposed to each other along a direction perpendicular to a surface of the board, one or a plurality of drive devices which are arranged in a first region of the first wiring layer, and which are configured to generate the drive signal configured to jet a liquid from the nozzle, and a deformation suppression part which is disposed in a second region of the second wiring layer, and which is configured to suppress a deformation of the flexible board.

A liquid jet head according to an embodiment of the present disclosure includes the flexible board according to the embodiment of the present disclosure described above, and a jet section which is configured to jet the liquid based on the drive signal output from the flexible board, and which includes a plurality of nozzles.

A liquid jet recording apparatus according to an embodiment of the present disclosure includes the liquid jet head according to the embodiment of the present disclosure.

According to the flexible board, the liquid jet head, and the liquid jet recording apparatus related to the embodiment of the present disclosure, it becomes possible to easily improve the reliability.

### BRIEF DESCRIPTION OF THE DRAWINGS

FIG. 1 is a block diagram showing an outline configuration example of a liquid jet recording apparatus according to an embodiment of the present disclosure.

FIG. 2 is a perspective view schematically showing an outline configuration example of a liquid jet head shown in FIG. 1.

FIG. 3 is a cross-sectional view schematically showing a configuration example of the liquid jet head shown in FIG. 2.

FIG. 4 is a plan view schematically showing a detailed configuration example of flexible boards shown in FIG. 2 and FIG. 3.

FIG. 5 is another plan view schematically showing the detailed configuration example of the flexible boards shown in FIG. 2 and FIG. 3.

FIG. 6 is a plan view schematically showing an arrangement configuration example of wiring patterns and so on in a flexible board related to a comparative example.

FIG. 7 is a perspective view schematically showing an arrangement configuration example of a deformation suppression parts and so on related to the embodiment.

FIG. 8 is another perspective view schematically showing an arrangement configuration example of the deformation suppression parts and so on related to the embodiment.

FIG. 9 is a cross-sectional view schematically showing the arrangement configuration example of the deformation suppression part and so on shown in FIG. 8.

FIG. 10 is a plan view schematically showing an arrangement configuration example of a deformation suppression part and so on related to Practical Example 1.

FIG. 11 is a plan view schematically showing an arrangement configuration example of a deformation suppression part and so on related to Practical Example 2.

FIG. 12 is a plan view schematically showing an arrangement configuration example of a deformation suppression part and so on related to Practical Example 3.

FIG. 13 is a plan view schematically showing an arrangement configuration example of a deformation suppression part and so on related to Practical Example 4.

FIG. 14 is a plan view schematically showing an arrangement configuration example of a deformation suppression part and so on related to Practical Example 5.

FIG. 15 is a plan view schematically showing an arrangement configuration example of a deformation suppression part and so on related to Practical Example 6.

FIG. 16 is a plan view schematically showing an arrangement configuration example of a deformation suppression part and so on related to Practical Example 7.

### DETAILED DESCRIPTION OF THE PREFERRED EMBODIMENTS

An embodiment of the present disclosure will hereinafter be described in detail with reference to the drawings. It should be noted that the description will be presented in the following order.
1. Embodiment (an example of a flexible board including a deformation suppression parts having a variety of configurations)
2. Modified Examples

### 1. EMBODIMENT

### [Outline Configuration of Printer 5]

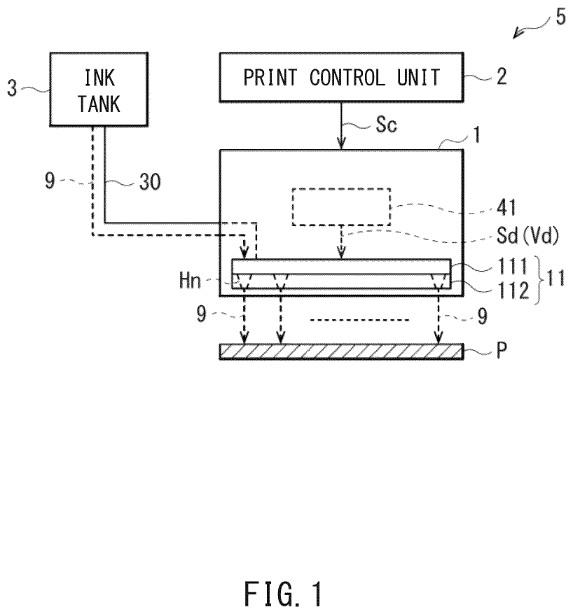

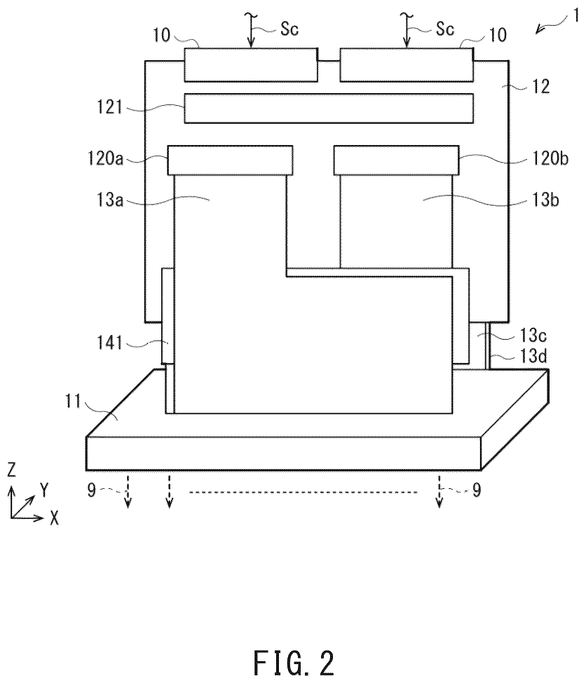

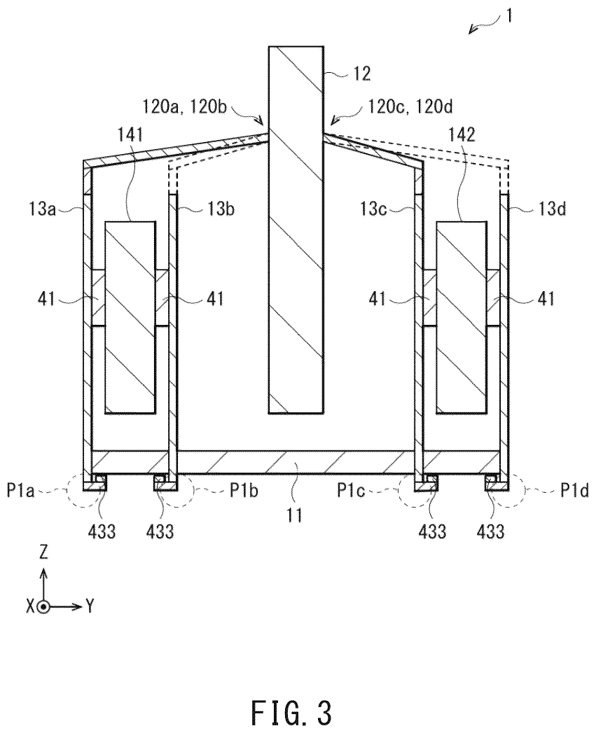

FIG. 1 is a block diagram showing an outline configuration example of a printer 5 as a liquid jet recording apparatus according to an embodiment of the present disclosure. FIG. 2 is a perspective view schematically showing an outline configuration example of an inkjet head 1 as a liquid jet head shown in FIG. 1. FIG. 3 is a cross-sectional view (a Y-Z cross-sectional view) schematically showing a configuration example of the inkjet head 1 shown in FIG. 2. It should be noted that a scale size of each of the members is accordingly altered so that the member is shown in a recognizable size in the drawings used in the description of the present specification.

The printer 5 is an inkjet printer for performing recording (printing) of images, characters, and the like on a recording target medium (e.g., recording paper P shown in FIG. 1) using ink 9 described later. As shown in FIG. 1, the printer 5 is provided with the inkjet head 1, a print control unit 2, and an ink tank 3.

It should be noted that the inkjet head 1 corresponds to a specific example of a “liquid jet head” in the present disclosure, and the printer 5 corresponds to a specific example of a “liquid jet recording apparatus” in the present disclosure. Further, the ink 9 corresponds to a specific example of a “liquid” in the present disclosure.

### (A. Print Control Unit 2)

The print control unit 2 is for supplying the inkjet head 1 with a variety of types of information (data). Specifically, as shown in FIG. 1, the print control unit 2 is arranged to supply each of constituents (drive devices 41 described later and so on) in the inkjet head 1 with a print control signal Sc.

It should be noted that the print control signal Sc is arranged to include, for example, image data, an ejection timing signal, and a power-supply voltage for making the inkjet head 1 operate.

### (B. Ink Tank 3)

The ink tanks 3 are tanks for containing the ink 9 inside. As shown in FIG. 1, it is arranged that the ink 9 in the ink tank 3 is supplied to the inside (a jet section 11 described later) of the inkjet head 1 via an ink supply tube 30. It should be noted that such an ink supply tube 30 is formed of, for example, a flexible hose having flexibility.

### (C. Inkjet Head 1)

The inkjet head 1 is a head for jetting (ejecting) the ink 9 shaped like a droplet from a plurality of nozzle holes Hn described later to the recording paper P as represented by dotted arrows in FIG. 1 to thereby perform recording of images, characters, and so on. As shown in, for example, FIG. 2 and FIG. 3, the inkjet head 1 is provided with a single jet section 11, a single I/F (interface) board 12, four flexible boards 13a, 13b, 13c, and 13d, and two cooling units 141, 142.

### (C-1. I/F Board 12)

As shown in FIG. 2 and FIG. 3, the I/F board 12 is provided with two connectors 10, four connectors 120a, 120b, 120c, and 120d, and a circuit arrangement area 121.

As shown in FIG. 2, the connectors 10 are each a part (a connector part) for inputting the print control signal Sc, which is described above, and which is supplied from the print control unit 2 toward the inkjet head 1 (the flexible boards 13a, 13b, 13c, and 13d described later).

The connectors 120a, 120b, 120c, and 120d are parts (connector parts) for electrically coupling the I/F board 12 and the flexible boards 13a, 13b, 13c, and 13d, respectively.

The circuit arrangement area 121 is an area where a variety of circuits are arranged on the I/F board 12. It should be noted that it is also possible to arrange that such a circuit arrangement area is also disposed in other regions on the I/F board 12.

### (C-2. Jet Section 11)

As shown in FIG. 1, the jet section 11 is a part which has the plurality of nozzle holes Hn, and which jets the ink 9 from these nozzle holes Hn. It is arranged that such jet of the ink 9 is performed in accordance with drive signals Sd (drive voltages Vd) supplied from the drive devices 41 described later on each of the flexible boards 13a, 13b, 13c, and 13d (see FIG. 1).

As shown in FIG. 1, such a jet section 11 is configured including an actuator plate 111 and a nozzle plate 112.

### (Nozzle Plate 112)

The nozzle plate 112 is a plate formed of a film material such as polyimide, or a metal material, and has the plurality of nozzle holes Hn described above as shown in FIG. 1. These nozzle holes Hn are formed side by side at predetermined intervals, and each have, for example, a circular shape. It should be noted that these nozzle holes Hn each correspond to a specific example of a “nozzle” in the present disclosure.

Specifically, in the example of the jet section 11 shown in FIG. 2, the jet section 11 is configured with a plurality of nozzle arrays (four nozzle arrays) each of which has the plurality of nozzle holes Hn in the nozzle plate 112 arranged along an array direction (an X-axis direction). Further, these four nozzle arrays are arranged side by side along a direction (a Y-axis direction) perpendicular to the array direction.

### (Actuator Plate 111)

The actuator plate 111 is a plate formed of a piezoelectric material such as PZT (lead zirconate titanate). The actuator plate 111 is provided with a plurality of channels (pressure chambers). These channels are each a part for applying pressure to the ink 9, and are arranged side by side so as to be parallel to each other at predetermined intervals. Each of the channels is partitioned with drive walls (not shown) formed of a piezoelectric body, and forms a groove part having a recessed shape in a cross-sectional view.

As such channels, there exist ejection channels for ejecting the ink 9, and dummy channels (non-ejection channels) which do not eject the ink 9. In other words, it is arranged that the ejection channels are filled with the ink 9 on the one hand, but the dummy channels are not filled with the ink 9 on the other hand. It should be noted that it is arranged that filling of each of the ejection channels with the ink 9 is performed via, for example, a flow channel (a common flow channel) commonly communicated with such ejection channels. Further, it is arranged that each of the ejection channels is individually communicated with the nozzle hole Hn in the nozzle plate 112 on the one hand, but each of the dummy channels is not communicated with the nozzle hole Hn on the other hand. These ejection channels and dummy channels are alternately arranged side by side along the array direction (the X-axis direction) described above.

Further, on the inner side surfaces opposed to each other in the drive walls described above, there are respectively disposed drive electrodes. As the drive electrodes, there exist common electrodes disposed on the inner side surfaces facing the ejection channels, and active electrodes (individual electrodes) disposed on the inner side surfaces facing the dummy channels. These drive electrodes and the drive devices 41 described later are electrically coupled to each other via each of the flexible boards 13a, 13b, 13c, and 13d. Thus, it is arranged that the drive voltages Vd (the drive signals Sd) described above are applied to the drive electrodes from the drive devices 41 via each of the flexible boards 13a, 13b, 13c, and 13d (see FIG. 1).

### (C-3. Flexible Boards 13a, 13b, 13c, and 13d)

The flexible boards 13a, 13b, 13c, and 13d are each a board for electrically coupling the I/F board 12 and the jet section 11 to each other as shown in FIG. 2 and FIG. 3. These flexible boards 13a, 13b, 13c, and 13d are arranged to individually control jet actions of the ink 9 in the four nozzle arrays in the nozzle plate 112 described above, respectively. Further, as indicated by the reference symbols P1a, P1b, P1c, and P1d in, for example, FIG. 3, it is arranged that the flexible boards 13a, 13b, 13c, and 13d are folded around places (around pressure-bonding electrodes 433) where the flexible boards 13a, 13b, 13c, and 13d are coupled to the jet section 11, respectively. It should be noted that it is arranged that electrical coupling between the pressure-bonding electrodes 433 and the jet section 11 is achieved by, for example, thermocompression bonding using an anisotropic conductive film (ACF).

On each of such flexible boards 13a, 13b, 13c, and 13d, there are individually mounted the drive devices 41 (see FIG. 3). These drive devices 41 are each a device for outputting the drive signals Sd (the drive voltages Vd) for jetting the ink 9 from the nozzle holes Hn in the corresponding nozzle array in the jet section 11. Therefore, it is arranged that such drive signals Sd are output from each of the flexible boards 13a, 13b, 13c, and 13d to the jet section 11. It should be noted that such drive devices 41 are each formed of, for example, an application specific integrated circuit (ASIC).

Further, these drive devices 41 are arranged to be cooled by the cooling units 141, 142 described above. Specifically, as shown in FIG. 3, the cooling unit 141 is fixedly arranged between the drive devices 41 on the flexible boards 13a, 13b, and by pressing the cooling unit 141 against each of these drive devices 41, the drive devices 41 are cooled. Similarly, the cooling unit 142 is fixedly arranged between the drive devices 41 on the flexible boards 13c, 13d, and by pressing the cooling unit 142 against each of these drive devices 41, the drive devices 41 are cooled. It should be noted that such cooling units 141, 142 can each be configured using a variety of types of cooling mechanisms.

[Detailed Configuration of Flexible Boards 13a, 13b, 13c, and 13d]

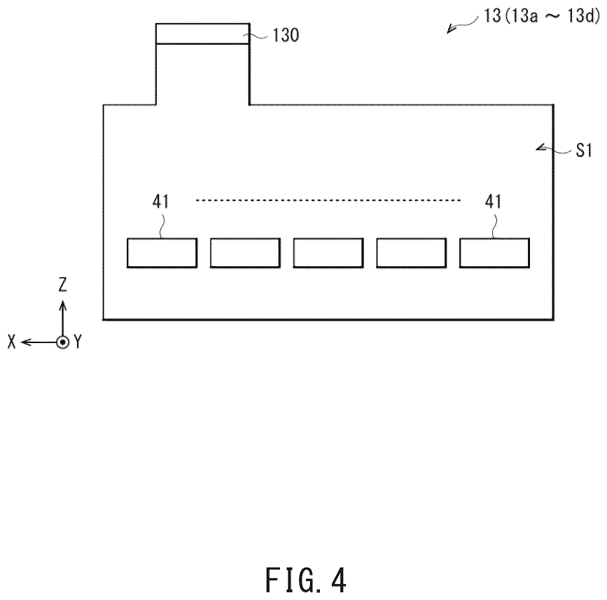

Subsequently, a detailed configuration example of the flexible boards 13a, 13b, 13c, and 13d described above will be described while being compared to a configuration of a comparative example with reference to FIG. 4 through FIG. 9 in addition to FIG. 1 through FIG. 3.

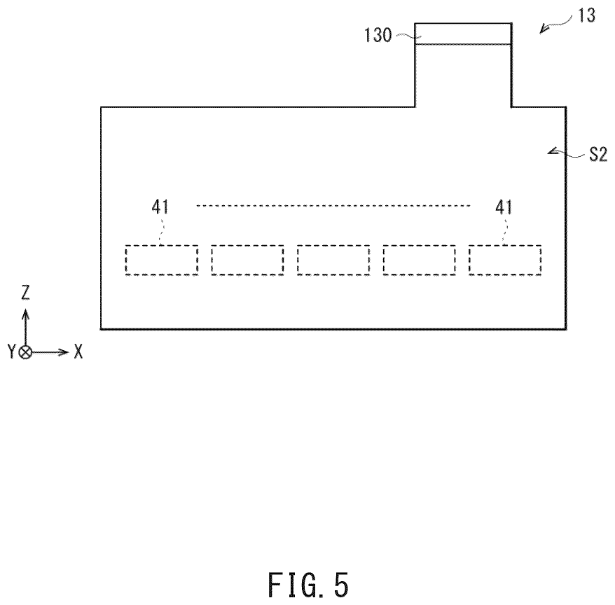

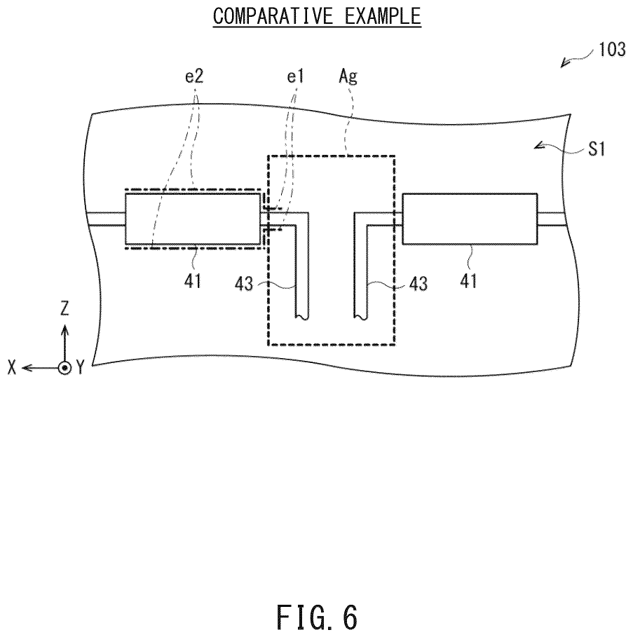

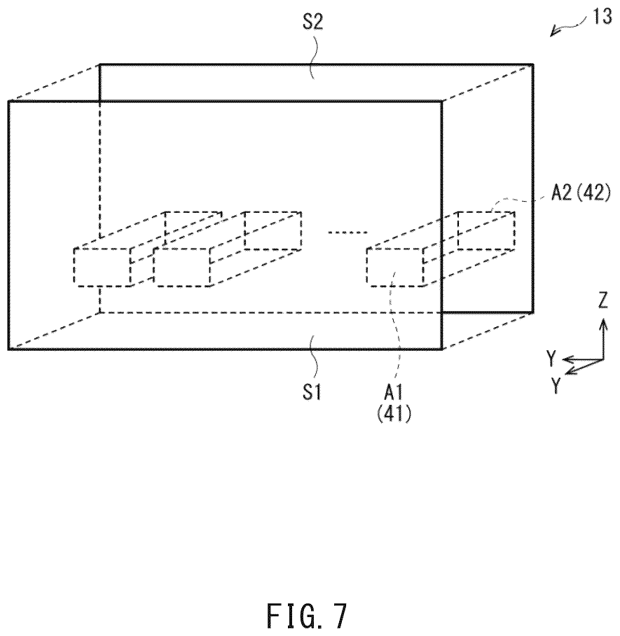

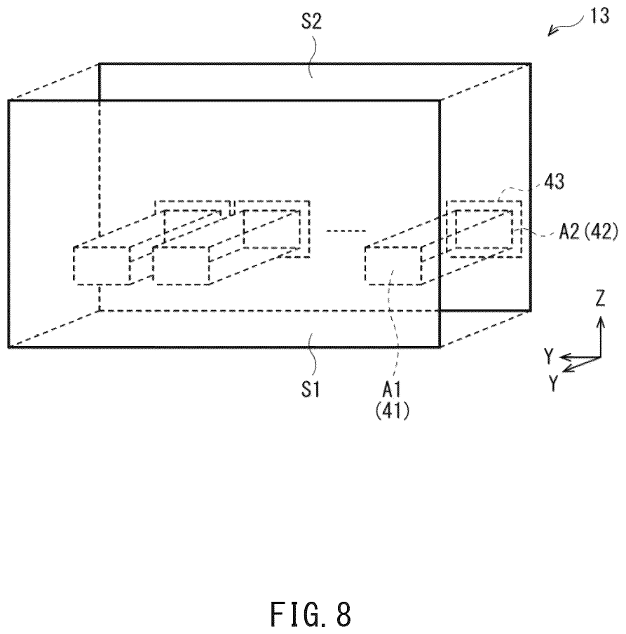

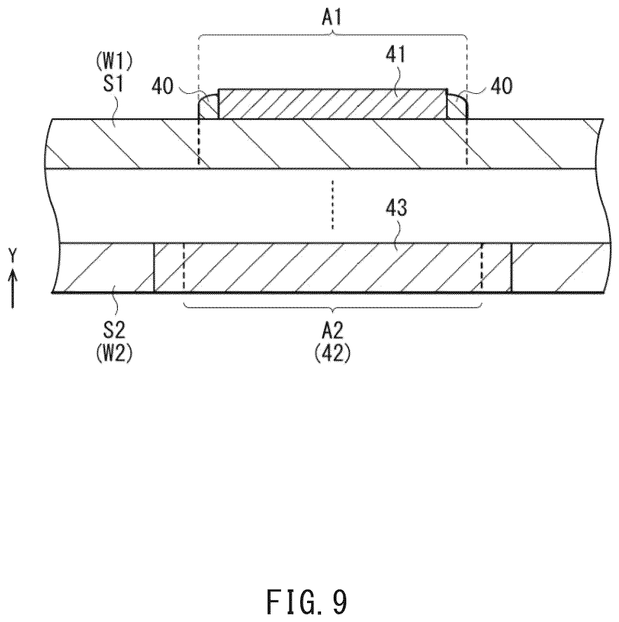

FIG. 4 and FIG. 5 are plan views (Z-X plan views) schematically showing a detailed configuration example of the flexible boards 13a to 13d (hereinafter collectively referred to as flexible boards 13 as appropriate) shown in FIG. 2 and FIG. 3. Specifically, FIG. 4 shows a planar configuration example at an obverse surface S1 side described later in the flexible board 13, and FIG. 5 shows a planar configuration example at a reverse surface S2 side described later in the flexible board 13, respectively. Further, FIG. 6 is a plan view (Z-X plan view) schematically showing an arrangement configuration example of a wiring pattern 43 in the vicinity of an inter-device region Ag described later in a related-art flexible board (a flexible board 103) related to the comparative example. FIG. 7 and FIG. 8 are each a perspective view schematically showing an arrangement configuration example of the deformation suppression parts 42 and so on described later in the present embodiment. FIG. 9 is a cross-sectional view schematically showing the arrangement configuration example of the deformation suppression parts 42 and so on shown in FIG. 8.

First, the flexible boards 13 are each formed as a double-sided board with a multilayered structure including the obverse surface S1 and the reverse surface S2. Specifically, the flexible boards 13 each have a first wiring layer W1 at the obverse surface S1 side and a second wiring layer W2 at the reverse surface S2 side opposed to each other along a direction (the Y-axis direction) perpendicular to the board surfaces (a Z-X plane) as wiring layers of such a multilayered structure (double-layered structure) (see FIG. 9). It should be noted that the wiring layers in the flexible board 13 may have, for example, a structure of three or more layers including the first wiring layer W1 and the second wiring layer W2 described above.

Further, as shown in FIG. 4, FIG. 5, and FIG. 7 through FIG. 9, the flexible boards 13 each have a single drive device 41 or a plurality of drive devices 41 (five drive devices 41 in this example) described above, a mold part 40, wiring patterns 43, a terminal section 130, and the deformation suppression parts 42.

As described above, the drive devices 41 are disposed on (the first wiring layer W1 at the obverse surface S1 side of) the flexible board 13. Specifically, as shown in, for example, FIG. 7 to FIG. 9, the drive device 41 is disposed in a first region A1 of the first wiring layer W1. It should be noted that as shown in, for example, FIG. 9, the mold part 40 is disposed on the periphery of the drive device 41 in the first region A1 of the first wiring layer W1. Further, in the example shown in FIG. 4, FIG. 5, FIG. 7, and FIG. 8, the plurality of drive devices 41 (the five drive devices 41 in this example) is arranged side by side along the X-axis direction (the longitudinal direction of the flexible board 13) on the flexible board 13.

The wiring patterns 43 are patterns of a variety of wiring lines to be electrically coupled to the drive devices 41. As the wiring patterns 43 there are included, for example, signal wiring patterns corresponding to wiring lines of a variety of signals, power supply wiring patterns corresponding to wiring lines of a variety of power supplies, ground wiring patterns corresponding to the ground wiring lines, and so on.

The terminal section 130 is arranged (see FIG. 4 and FIG. 5) in an end-portion region at the I/F board 12 side in the flexible board 13, and includes a plurality of terminals for electrically coupling the flexible board 13 and the I/F board 12 to each other. In other words, the terminal section 130 is a portion to be inserted into one of the connectors 120a to 120d on the I/F board 12 as another board.

The deformation suppression parts 42 are each a part which is disposed in a second region A2 of the second wiring layer W2 (see FIG. 7 to FIG. 9), and suppresses the deformation of the flexible board 13. The reason that the deformation of the flexible board 13 is suppressed in such a manner will hereinafter be described with reference also to the comparative example shown in FIG. 6.

First, in the flexible board 103 in the comparative example shown in FIG. 6, it is arranged that folding between the drive devices 41 is prevented by disposing the wiring pattern 43 in the region (the inter-device region Ag) between the drive devices 41 to increase the rigidity of the inter-device region Ag. However, when adopting such a configuration, a region low in rigidity occurs in a boundary between the wiring pattern 43 and an end portion (end portion e1) of the drive device 41, stress is applied to the boundary when the flexible board 103 is folded, and there is a possibility that separation of the drive device 41 mounted thereon is incurred. Further, also when the flexible board 103 is folded in an end portion (the end portion e2) which is not sandwiched by the drive devices 41, stress is directly applied to the end portion, and there is a possibility that separation of the drive device 41 mounted thereon is incurred in substantially the same manner.

Therefore, in the flexible board 13 in the present embodiment, the deformation suppression parts 42 for suppressing the deformation of the flexible board 13 are each disposed on the second wiring layer W2 (in the second region A2) different from the first wiring layer W1 on which the drive devices 41 are disposed. Specifically, in the example in FIG. 7 to FIG. 9, it is arranged that the second region A2 in which the deformation suppression part 42 is disposed overlaps the entire area of the first region A1 including an arrangement area of the drive device 41. Further, as shown in, for example, FIG. 7 and FIG. 8, on the flexible board 13, the second regions A2 are arranged so as to be separated from each other for the respective drive devices 41.

Further, in the example in FIG. 8 and FIG. 9, the deformation suppression part 42 is configured using the wiring pattern 43 on the second wiring layer W2. It should be noted that the wiring pattern 43 constituting such a deformation suppression part 42 is set at, for example, a predetermined power supply potential or a ground potential. Further, as such a ground potential, there can be cited, for example, a ground potential for a predetermined signal line.

### [Practical Examples Related to Configuration of Deformation Suppression Part 42]

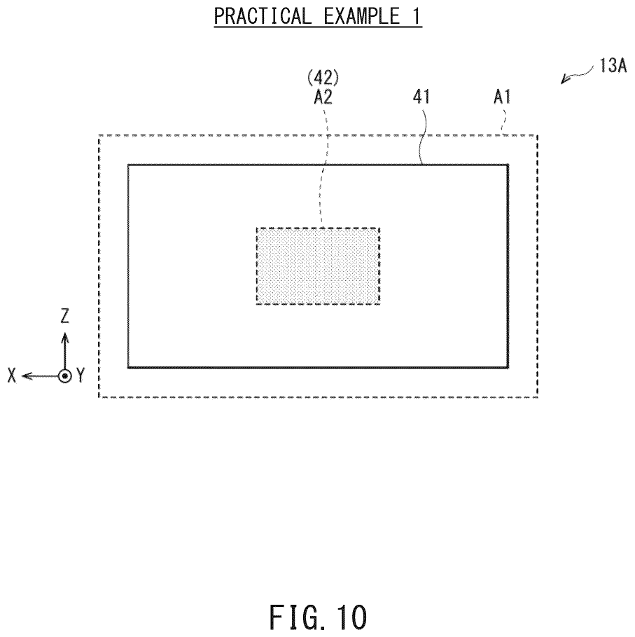

Here, practical examples (Practical Examples 1 to 7) related to the configuration of such a deformation suppression part 42 will be described in detail with reference to FIG. 10 to FIG. 16 in addition to FIG. 1 to FIG. 9.

FIG. 10 to FIG. 15 are plan views (Z-X plan views) schematically showing arrangement configuration examples of the deformation suppression parts 42 and so on in the flexible boards (flexible boards 13A to 13G) according to Practical Examples 1 to 7. Specifically, FIG. 10 to FIG. 16 described above schematically show correspondence relationships between the arrangement area (mounting area) of the drive device 41, the first region A1 and the second region A2 described above, and the arrangement area of the deformation suppression part 42 on the flexible boards 13A to 13G.

First, in the flexible board 13A in Practical Example 1 shown in FIG. 10, the second region A2 in which the deformation suppression part 42 is disposed overlaps at least a part (a part of the first region A1 in the example in FIG. 10) in the first region A1 including the arrangement area of the drive device 41. It should be noted that in contrast, in the example in FIG. 7 to FIG. 9, the second region A2 in which the deformation suppression part 42 is disposed overlaps the entire area of the first region A1 including the arrangement area of the drive device 41.

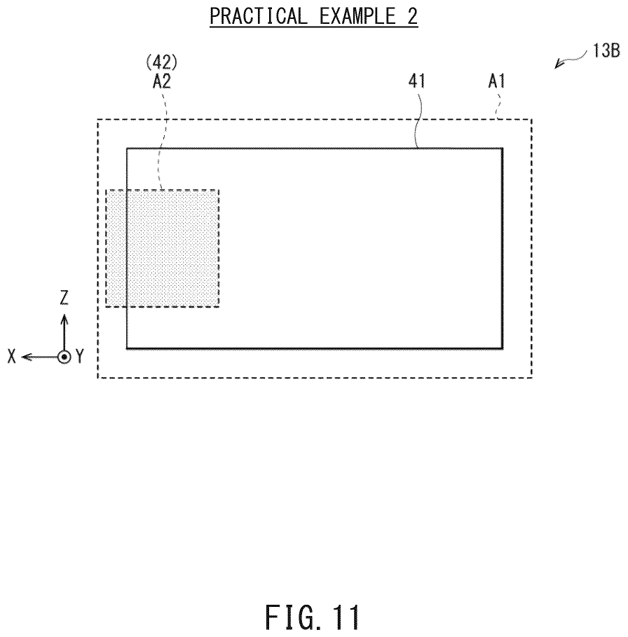

Further, in the flexible board 13B in Practical Example 2 shown in FIG. 11, the second region A2 in which the deformation suppression part 42 is disposed overlaps at least a part (a part of an end portion of the drive device 41 in the example in FIG. 11) of the drive device 41 in the first region A1.

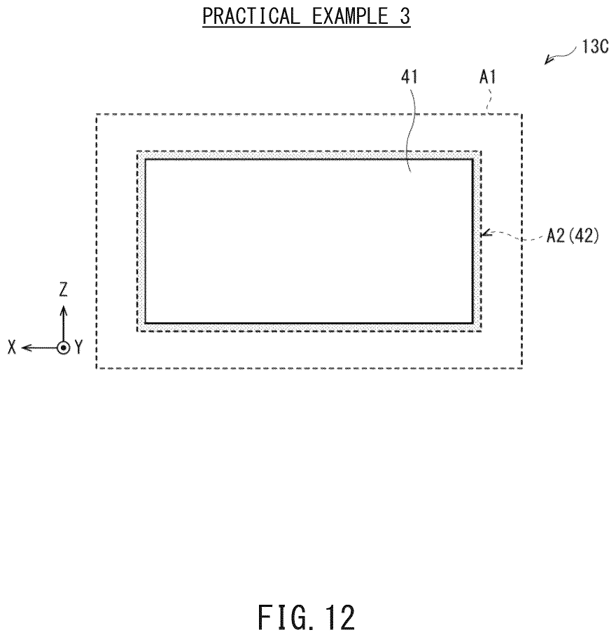

In the flexible board 13C in Practical Example 3 shown in FIG. 12, the second region A2 in which the deformation suppression part 42 is disposed is disposed along an outer circumference of the drive device 41 in the first region A1. It should be noted that coupling electrodes (not shown) to the flexible board 13C, for example, are arranged side by side in the vicinity of the outer circumference of the drive device 41. Therefore, when arranging the deformation suppression part 42 so as to include the coupling electrodes, it becomes necessary to provide a width of, for example, about ±0.2 mm from the outer circumference (an outer frame) of the drive device 41.

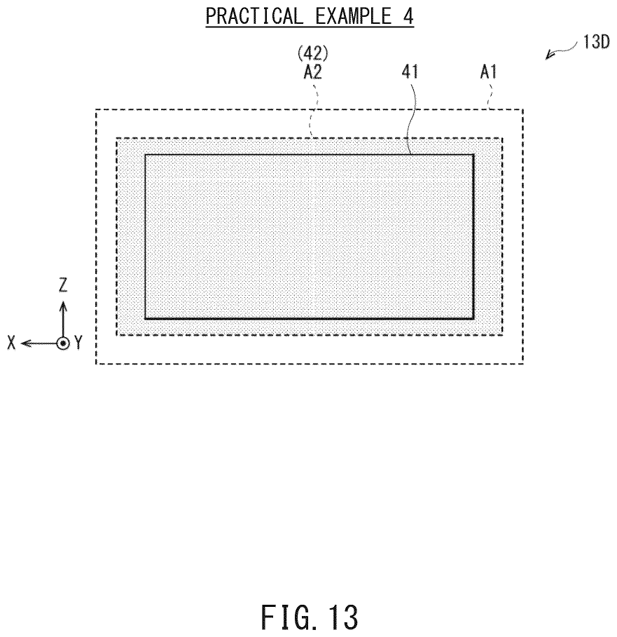

In the flexible board 13D in Practical Example 4 shown in FIG. 13, the second region A2 in which the deformation suppression part 42 is disposed overlaps the entire arrangement area of the drive device 41 in the first region A1.

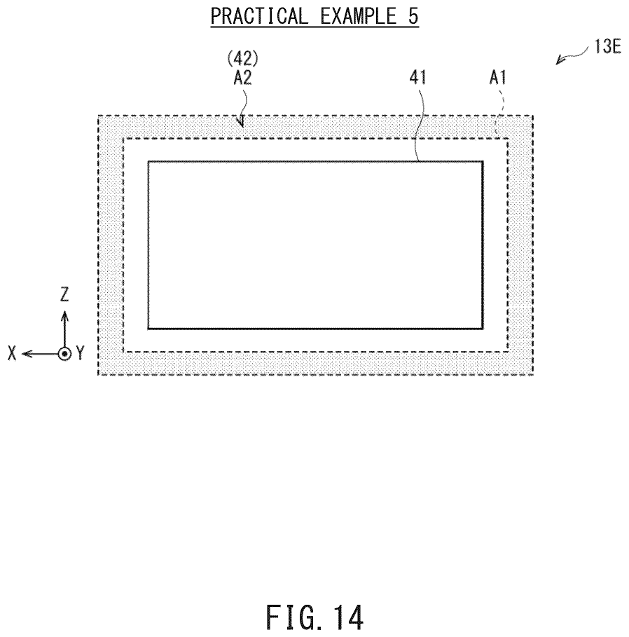

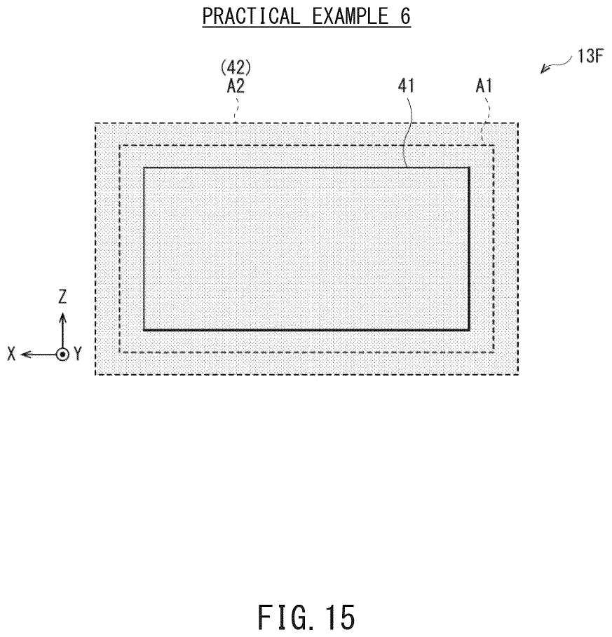

In the flexible board 13E in Practical Example 5 shown in FIG. 14, the second region A2 in which the deformation suppression part 42 is disposed is disposed along an outer circumference of the first region A1 including the arrangement area of the drive device 41 so as to be separated from the arrangement area of the drive device 41. It should be noted that when arranging the deformation suppression part 42 while protecting the mold part 40 described above, it becomes necessary to provide a width of, for example, about ±1.0 mm from the outer circumference (an outer frame) of the first region A1. On the other hand, in the flexible board 13F in Practical Example 6 shown in FIG. 15, the second region A2 in which the deformation suppression part 42 is disposed overlaps the entire area of the first region A1 including the arrangement area of the drive device 41.

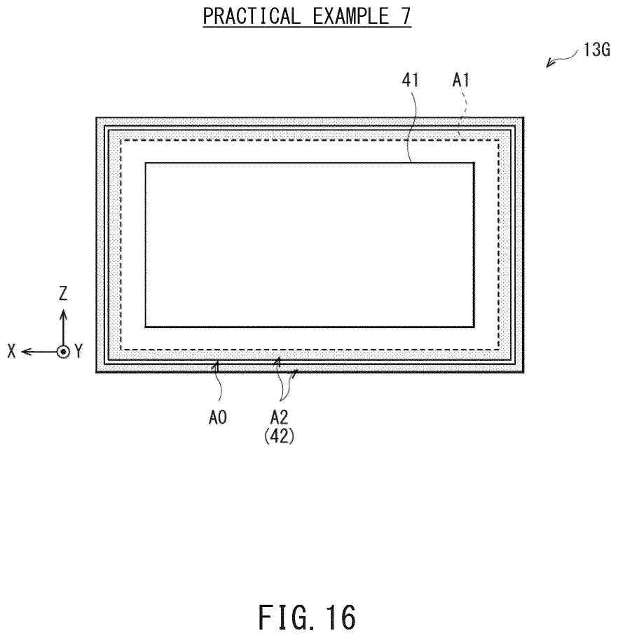

Further, in the flexible board 13G in Practical Example 7 shown in FIG. 16, similarly to the flexible board 13E described above, the second region A2 in which the deformation suppression part 42 is disposed is disposed along the outer circumference of the first region A1 including the arrangement area of the drive device 41 so as to be separated from the arrangement area of the drive device 41. However, in the flexible board 13G, unlike the flexible board 13E, the second region A2 has an outside region including a cutout part A0 outside the first region A1. That is, the second region A2 at the inner circumferential side and the second region A2 at the outer circumferential side are disposed across the cutout part A0 where the deformation suppression part 42 is not disposed. It should be noted that it may be arranged that the deformation suppression part 42 (the second region A2) at the inner circumferential side of the cutout part A0 is not separated from the arrangement area of the drive device 41 unlike the case of Practical Example 7 shown in FIG. 16. Further, regarding the shape of the cutout part A0, any shape can be adopted as long as the shape is obtained by cutting the pattern of the deformation suppression part 42 at the outer circumferential side of the first region A1, and the shape surrounding the first region A1, for example, is not required.

### [Operations and Functions/Advantages]

### (A. Basic Operation of Printer 5)

In the printer 5, a recording operation (a printing operation) of images, characters, and so on to the recording target medium (the recording paper P or the like) is performed using such a jet operation of the ink 9 by the inkjet head 1 as described below. Specifically, in the inkjet head 1 according to the present embodiment, the jet operation of the ink 9 using a shear mode is performed in the following manner.

First, the drive devices 41 on each of the flexible boards 13 (13a, 13b, 13c, and 13d) each apply the drive voltages Vd (the drive signals Sd) to the drive electrodes (the common electrodes and the active electrodes) described above in the actuator plate 111 in the jet section 11. Specifically, each of the drive devices 41 applies the drive voltage Vd to the drive electrodes disposed on the pair of drive walls partitioning the ejection channel described above. Thus, the pair of drive walls each deform so as to protrude toward the dummy channel adjacent to the ejection channel.

On this occasion, it results in that the drive wall makes a flexion deformation to have a V shape centering on the intermediate position in the depth direction in the drive wall. Further, due to such a flexion deformation of the drive wall, the ejection channel deforms as if the ejection channel bulges. As described above, due to the flexion deformation caused by a piezoelectric thickness-shear effect in the pair of drive walls, the volume of the ejection channel increases. Further, by the volume of the ejection channel increasing, the ink 9 is induced into the ejection channel as a result.

Subsequently, the ink 9 induced into the ejection channel in such a manner turns to a pressure wave to propagate to the inside of the ejection channel. Then, the drive voltage Vd to be applied to the drive electrodes becomes 0 (zero) V at the timing at which the pressure wave has reached the nozzle hole Hn of the nozzle plate 112 (or timing around that timing). Thus, the drive walls are restored from the state of the flexion deformation described above, and as a result, the volume of the ejection channel having once increased is restored again.

In such a manner, the pressure inside the ejection channel increases in the process that the volume of the ejection channel is restored, and thus, the ink 9 in the ejection channel is pressurized. As a result, the ink 9 shaped like a droplet is ejected (see FIG. 1) toward the outside (toward the recording paper P) through the nozzle hole Hn. The jet operation (the ejection operation) of the ink 9 in the inkjet head 1 is performed in such a manner, and as a result, the recording operation of images, characters, and so on to the recording paper P is performed.

### (B. Functions/Advantages in Inkjet Head 1)

Then, the functions and the advantages in the inkjet head 1 according to the present embodiment will be described in detail.

### (B-1. Regarding Related-Art Inkjet Head)

First, in the related-art inkjet head, there is known a method in which a flexible board is used as a drive board for driving the inkjet head. Since the flexible board has flexibility, an arrangement of boards in the inkjet head, coupling to an actuator, and so on become easy. However, since the flexible board has the flexibility, it becomes difficult to handle the flexible board when assembling or the likes, which causes deterioration of the yield ratio. In particular, folding of the flexible board can occur in the end portion of the drive device which is a particularly large component out of the mounted components on the flexible board.

Therefore, in the flexible board 103 (see FIG. 6) in the comparative example described above, for example, it is arranged that folding between the drive devices 41 is prevented by disposing the wiring pattern 43 in the inter-device region Ag to increase the rigidity of the inter-device region Ag. However, when such a configuration is adopted, when the flexible board 103 is folded, the stress is applied in the vicinity of the end portions e1, e2 in such a manner as described above, and there is a possibility that the separation of the drive device 41 mounted thereon is incurred.

It can be said that it is difficult to easily improve the reliability of the flexible board in the flexible board (including the flexible board 103 in the comparative example) in the related-art inkjet head in such a manner.

### (B-2. Functions/Advantages)

In contrast, in the inkjet head 1 according to the present embodiment, since the flexible boards 13 (13A through 13F) have the following configuration, it is possible to obtain, for example, the following functions and advantages.

That is, first, in the flexible board 13 in the present embodiment, the deformation suppression parts 42 for suppressing the deformation of the flexible board 13 are each disposed on the second wiring layer W2 (in the second region A2) different from the first wiring layer W1 on which the drive devices 41 are disposed. Thus, since the deformation of the flexible board 13 is suppressed while a degree of freedom of wiring with respect to the drive device 41 on the first wiring layer W1 is maintained, it becomes easy to prevent the separation of the drive device 41 mounted thereon. As a result, in the present embodiment, compared to the comparative example described above and so on, it becomes possible to easily improve the reliability of the flexible board 13.

Further, in the present embodiment, when it is arranged that the second region A2 described above overlaps at least a part in the first region A1 including the arrangement area of the drive device 41, the following is achieved. In other words, when mounting pads (electrodes to be coupled to the board) of the drive device 41 are located at inner side of the outer shape of the drive device 41, it becomes possible to protect coupling between the mounting pads and the board.

Further, in the present embodiment, when it is arranged that the second region A2 described above overlaps at least a part of the end portion of the drive device 41 in the first region A1, it becomes possible to prevent the separation of the drive device 41 mounted thereon in the vicinity of the end portion of the drive device 41.

In addition, in the present embodiment, when it is arranged that the second region A2 described above is disposed along the outer circumference of the drive device 41 in the first region A1, the following is achieved. That is, it becomes possible to protect (prevent the separation of the drive device 41 mounted thereon in the vicinity of all the end portions) all the end portion of the drive device 41.

Further, in the present embodiment, when it is arranged that the second region A2 described above overlaps the entire area of the drive device 41 in the first region A1, it becomes possible to protect not only the vicinity of the end portion of the drive device 41 but also the entire arrangement area of the drive device 41.

Further, in the present embodiment, when it is arranged that the second region A2 described above is disposed along the outer circumference of the first region A1 so as to be separated from the arrangement area of the drive device 41, the following is achieved. That is, it becomes possible to prevent the separation between the end portion of the mold part 40 and the board.

In addition, in the present embodiment, when it is arranged that the second region A2 described above overlaps the entire area of the first region A1, it becomes possible to further increase the strength of the flexible board 13 to further suppress the folding.

Further, in the present embodiment, when it is arranged that the second region A2 described above has the outside region including the cutout part A0 outside the first region A1, the following is achieved. In other words, by cutting the pattern of another region than the first region A1, it becomes possible to distribute the folding stress on the flexible board 13 to another region than the periphery of the drive device 41.

Further, in the present embodiment, since it is arranged that the plurality of drive devices 41 are arranged side by side along the longitudinal direction (the X-axis direction) of the flexible board 13, the following is achieved. In other words, the path of the wiring pattern 43 on the flexible board 13 becomes short and simple. Therefore, it becomes possible to achieve a reduction in size of the flexible board 13.

In addition, in the present embodiment, since it is arranged that the second regions A2 are arranged so as to be separated from each other for the respective drive devices 41, it becomes possible to arrange other wiring patterns 43 in a region (the inter-device region Ag) between the drive devices 41.

Further, in the present embodiment, since it is arranged that the deformation suppression part 42 is configured using the wiring pattern 43 on the second wiring layer W2, the following is achieved. In other words, by performing reinforcement using such wiring pattern 43, it is possible to partially reinforce the flexible board 13, and by using the same material as that of other wiring patterns 43, it becomes possible to achieve commonization of the manufacturing step.

Further, in the present embodiment, when it is arranged that the wiring pattern 43 constituting the deformation suppression part 42 is set at the ground potential, it becomes possible to prevent the noise or to obtain the heat radiation effect.

In addition, in the present embodiment, when the ground potential set to the wiring pattern 43 described above is the ground potential for a predetermined signal line, it becomes possible to suppress the heat generation compared to the case of the power supply potential due to an influence of the voltage.

### 2. MODIFIED EXAMPLES

The present disclosure is described hereinabove citing the embodiment and some practical examples, but the present disclosure is not limited to the embodiment and so on, and a variety of modifications can be adopted.

For example, in the embodiment and so on described above, the description is presented specifically citing the configuration examples (the shapes, the arrangements, the number and so on) of each of the members in the printer and the inkjet head, but those described in the above embodiment and so on are not limitations, and it is possible to adopt other shapes, arrangements, numbers and so on.

Specifically, for example, in the embodiment and so on described above, the description is presented specifically citing the configuration examples (the shapes, the arrangement, the number, and so on) of the flexible boards, the drive devices, a variety of wiring patterns, and so on, but these configuration examples are not limited to those described in the above embodiment and so on. For example, in the embodiment and so on described above, there is described the example when the plurality of drive boards are disposed inside the inkjet head, but this example is not a limitation, and it is possible to arrange that, for example, just one drive board is disposed alone inside the inkjet head. Further, in the embodiment and so on described above, there is described the example when the plurality of drive devices are disposed on the drive board, but this example is not a limitation, and it is possible to arrange that, for example, just one drive device is disposed on the drive board. Further, in the embodiment and so on described above, the shape of the drive device is assumed to be the rectangular shape, but this example is not a limitation, and the shape of the drive device can be, for example, a square shape.

Further, a variety of types of structures can be adopted as the structure of the inkjet head. Specifically, it is possible to adopt, for example, a so-called side-shoot type inkjet head which ejects the ink 9 from a central portion in the extending direction of each of the ejection channels in the actuator plate 111. Alternatively, it is possible to adopt, for example, a so-called edge-shoot type inkjet head for ejecting the ink 9 along the extending direction of each of the ejection channels. Further, the type of the printer is not limited to the type described in the above embodiment and so on, and it is possible to apply a variety of types such as a micro electro-mechanical systems (MEMS) type.

Further, for example, it is possible to apply the present disclosure to either of an inkjet head of a circulation type which uses the ink 9 while circulating the ink 9 between the ink tank and the inkjet head, and an inkjet head of a non-circulation type which uses the ink 9 without circulating the ink 9.

Further, the series of processing described in the above embodiments and so on can be arranged to be performed by hardware (a circuit), or can also be arranged to be performed by software (a program). When it is arranged that the series of processing is performed by the software, the software is constituted by a program group for making the computer perform the functions. The programs can be incorporated in advance in the computer described above to be used by the computer, for example, or can also be installed in the computer described above from a network or a recording medium to be used by the computer.

Further, in the embodiment and so on described above, the description is presented citing the printer 5 (the inkjet printer) as a specific example of the “liquid jet recording apparatus” in the present disclosure, but this example is not a limitation, and it is also possible to apply the present disclosure to other apparatuses than the inkjet printer. In other words, it is also possible to arrange that the “liquid jet head” (the inkjet head) of the present disclosure is applied to other apparatuses than the inkjet printer. Specifically, it is also possible to arrange that the “liquid jet head” of the present disclosure is applied to an apparatus such as a facsimile or an on-demand printer.

In addition, it is also possible to apply the variety of examples described hereinabove in arbitrary combination.

It should be noted that the advantages described in the present specification are illustrative only, but are not a limitation, and other advantages can also be provided.

Further, the present disclosure can also take the following configurations.

A flexible board configured to output a drive signal to be applied to a liquid jet head having a plurality of nozzles, including a plurality of wiring layers including a first wiring layer and a second wiring layer opposed to each other along a direction perpendicular to a surface of the board, one or a plurality of drive devices which are arranged in a first region of the first wiring layer, and which are configured to generate the drive signal configured to jet a liquid from the nozzle, and a deformation suppression part which is disposed in a second region of the second wiring layer, and which is configured to suppress a deformation of the flexible board.

The flexible board described in (1) above, wherein the second region overlaps at least a part of the first region.

The flexible board described in (2) above, wherein the second region overlaps at least a part of an end portion of the drive device in the first region.

The flexible board described in (2) above, wherein the second region is arranged along an outer circumference of the drive device in the first region.

The flexible board described in (2) above, wherein the second region overlaps an entire area of the drive device in the first region.

The flexible board described in (1) above, wherein the second region is arranged along an outer circumference of the first region so as to be separated from an arrangement area of the drive device.

The flexible board described in (1) above, wherein the second region overlaps an entire area of the first region.

The flexible board described in (1) above, wherein the second region has an outside region including a cutout part outside the first region.

The flexible board described in any of (1) to (8) above, wherein the plurality of drive devices are arranged side by side along a longitudinal direction of the flexible board.

The flexible board described in (9) above, wherein a plurality of the second regions are arranged so as to be separated from each other for the respective drive devices.

The flexible board described in any of (1) to (10) above, wherein the deformation suppression part is formed using a wiring pattern on the second wiring layer.

The flexible board described in (11) above, wherein the wiring pattern is set at a ground potential.

The flexible board described in (12) above, wherein the ground potential is a ground potential for a predetermined signal line.

A liquid jet head including the flexible board described in any of (1) to (13) above, and a jet section which is configured to jet the liquid based on the drive signal output from the flexible board, and which includes the plurality of nozzles.

A liquid jet recording apparatus including the liquid jet head described in (14) above.

What is claimed is:

1. A flexible board configured to output a drive signal to be applied to a liquid jet head having a plurality of nozzles, the flexible board comprising:
a plurality of wiring layers including a first wiring layer and a second wiring layer opposed to each other along a direction perpendicular to a surface of the board;
one or a plurality of drive devices which are arranged in a first region of the first wiring layer, and which are configured to generate the drive signal configured to jet a liquid from the nozzle; and
a deformation suppression part which is disposed in a second region of the second wiring layer, and which is configured to suppress a deformation of the flexible board.

2. The flexible board according to claim 1, wherein
the second region overlaps at least a part of the first region.

3. The flexible board according to claim 2, wherein
the second region overlaps at least a part of an end portion of the drive device in the first region.

4. The flexible board according to claim 2, wherein
the second region is arranged along an outer circumference of the drive device in the first region.

5. The flexible board according to claim 2, wherein
the second region overlaps an entire area of the drive device in the first region.

6. The flexible board according to claim 1, wherein
the second region is arranged along an outer circumference of the first region so as to be separated from an arrangement area of the drive device.

7. The flexible board according to claim 1, wherein
the second region overlaps an entire area of the first region.

8. The flexible board according to claim 1, wherein
the second region has an outside region including a cutout part outside the first region.

9. The flexible board according to claim 1, wherein
the plurality of drive devices are arranged side by side along a longitudinal direction of the flexible board.

10. The flexible board according to claim 9, wherein
a plurality of the second regions are arranged so as to be separated from each other for the respective drive devices.

11. The flexible board according to claim 1, wherein
the deformation suppression part is formed using a wiring pattern on the second wiring layer.

12. The flexible board according to claim 11, wherein
the wiring pattern is set at a ground potential.

13. The flexible board according to claim 12, wherein
the ground potential is a ground potential for a predetermined signal line.

14. A liquid jet head comprising:
the flexible board according to claim 1; and
a jet section which is configured to jet the liquid based on the drive signal output from the flexible board, and which includes the plurality of nozzles.

15. A liquid jet recording apparatus comprising the liquid jet head according to claim 14.
